(19) United States
(12) Patent Application Publication
(10) Pub. No.: US 2012/0156839 A1
(43) Pub. Date: Jun. 21, 2012

(54) Patterning of a Stressed Dielectric Material in a Contact Level Without Using an Underlying Etch Stop Layer

(75) Inventors: Thilo Scheiper, Dresden (DE); Sven Beyer, Dresden (DE); Jan Hoentschel, Dresden (DE); Stefan Flachowsky, Dresden (DE)

(73) Assignee: GLOBALFOUNDRIES INC., Grand Cayman (KY)

(21) Appl. No.: 13/191,870

(22) Filed: Jul. 27, 2011

(30) Foreign Application Priority Data
Dec. 16, 2010 (DE) 10 2010 063 298.8

(51) Int. Cl. H01L 21/8238

(52) U.S. Cl. 438/229; 257/E21.639

(57) ABSTRACT

An efficient strain-inducing mechanism may be implemented in the form of differently stressed material layers that are formed above transistors of different types. The strain-inducing dielectric materials may be formed so as to be in direct contact with the corresponding transistors, thereby enhancing the overall strain transfer efficiency. Moreover, the disclosed manufacturing strategy avoids or at least significantly reduces any interaction of reactive etch atmospheres used to pattern the strain-inducing material layers with metal silicide regions, which may be formed individually for each type of transistor.

### BACKGROUND OF THE INVENTION

1. Field of the Invention

Generally, the present disclosure relates to the field of integrated circuits, and, more particularly, to field effect transistors and manufacturing techniques on the basis of stressed dielectric layers formed above the transistors used for generating a different type of strain in channel regions of different transistor types.

2. Description of the Related Art

Integrated circuits are typically comprised of a large number of circuit elements located on a given chip area according to a specified circuit layout, wherein, in complex circuits, the field effect transistor represents one important circuit element that essentially determines performance of the integrated circuit. Generally, for advanced semiconductor devices, a plurality of process technologies are currently practiced, wherein, for complex circuitry based on field effect transistors, such as microprocessors, storage chips and the like, CMOS technology is currently one of the most promising approaches due to the superior characteristics in view of operating speed and/or power consumption and/or cost efficiency. During the fabrication of complex integrated circuits using CMOS technology, millions of complementary transistors, i.e., N-channel transistors and P-channel transistors, are formed on a substrate including a crystalline semiconductor layer. A field effect transistor, irrespective of whether an N-channel transistor or a P-channel transistor is considered, comprises so-called PN junctions that are formed by an interface of highly doped drain and source regions, with an inversely or weakly doped channel region disposed between the drain region and the source region. The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on, among other things, the dopant concentration, the mobility of the majority charge carriers and, for a given extension of the channel region in the transistor width direction, on the distance between the source and drain regions, which is also referred to as channel length. Therefore, reducing the channel length has been the dominant mechanism for steadily improving performance of the transistors and thus of the integrated circuits, thereby also increasing the overall packing density.

The shrinkage of the transistor dimensions, however, involves a plurality of issues associated therewith that have to be addressed so as to not unduly offset the advantages obtained by steadily decreasing the channel length of MOS transistors. One issue associated with reduced gate lengths is the occurrence of so-called short channel effects, which may result in a reduced controllability of the channel conductivity. Short channel effects may be countered by certain design techniques, some of which, however, may be accompanied by a reduction of the channel conductivity, thereby partially offsetting the advantages obtained by the reduction of critical dimensions.

In view of this situation, it has been proposed to enhance device performance of the transistor elements not only by reducing the transistor dimensions but also by increasing the charge carrier mobility in the channel region for a given channel length, thereby increasing the drive current capability and thus transistor performance. For example, the lattice structure in the channel region may be modified, for instance, by creating tensile or compressive strain therein, which results in a modified mobility for electrons and holes, respectively. For example, creating tensile strain in the channel region of a silicon layer having a standard crystallographic configuration may increase the mobility of electrons, which in turn may directly translate into a corresponding increase of the conductivity of N-type transistors. On the other hand, compressive strain in the channel region may increase the mobility of holes, thereby providing the potential for enhancing the performance of P-type transistors.

One efficient approach in this respect is a technique that enables the creation of desired strain conditions within the channel region of different transistor elements by adjusting the stress characteristics of a dielectric layer stack that is formed above the basic transistor structure. The dielectric layer stack typically comprises one or more dielectric layers which may be located close to the transistor and which may also be used in controlling a respective etch process in order to form contact openings to the gate and drain and source terminals. Therefore, an effective control of mechanical stress in the channel regions, i.e., effective stress engineering, may be accomplished by individually adjusting the internal stress of these layers, which are also referred to as contact etch stop layers, and by positioning a contact etch stop layer having an internal compressive stress above a P-channel transistor while positioning a contact etch stop layer having an internal tensile stress above an N-channel transistor, thereby creating compressive and tensile strain, respectively, in the corresponding channel regions.

Typically, the contact etch stop layer is formed by plasma enhanced chemical vapor deposition (PECVD) processes above the transistor, i.e., above the gate structure and the drain and source regions, wherein, for instance, silicon nitride may be used due to its high etch selectivity with respect to silicon dioxide, which is a well-established interlayer dielectric material. Furthermore, PECVD silicon nitride may be deposited with a high intrinsic stress, for example, up to 2 Giga Pascal (GPa) or significantly higher of compressive stress and up to 1 GPa and significantly higher of tensile stress, wherein the type and the magnitude of the intrinsic stress may be efficiently adjusted by selecting appropriate deposition parameters. For example, ion bombardment, deposition pressure, substrate temperature, gas flow rates and the like represent respective parameters that may be used for obtaining the desired intrinsic stress.

This strain-inducing mechanism is a very promising approach, in particular for silicon-on-insulator (SOI) devices, in which, for instance, other strain-inducing mechanisms may be less effective, such as embedded strain-inducing semiconductor alloys and the like. A typical process flow for selectively forming a tensile stressed dielectric material above N-channel transistors and a compressively stressed dielectric material above a P-channel transistor may include the following process steps. Initially, the basic transistor structures are completed, i.e., typically metal silicide regions are formed in the drain and source areas of the transistors after any high temperature processes, wherein, depending on the overall configuration of respective gate electrode structures, also a metal silicide is formed in a portion of the semiconductor-based electrode materials of the gate electrode structures. Since a plurality of etch processes are required, in particular for patterning the strain-inducing dielectric material that is to be deposited first, an etch stop liner is required, which may have to preserve integrity of the metal silicide regions. To this end, typically a silicon dioxide material is deposited on the basis of any appropriate deposition technique. Next, the strain-inducing dielectric material is formed, for instance as a tensile stressed dielectric material, wherein corresponding process parameters are appropriately controlled so as to obtain the high tensile stress level in the silicon nitride material, as is also discussed above. Thereafter, an etch mask, such as a resist mask, is formed by lithography techniques, followed by an etch process, such as a plasma assisted etch process for etching silicon nitride material, wherein the underlying silicon dioxide material may act as an etch stop layer. After the removal of the resist mask, the compressively stressed dielectric material is deposited by using appropriately selected process parameters in view of desired high internal stress level. It should be appreciated that typically upon depositing the first strain-inducing dielectric layer, an additional etch stop or etch control layer, such as a silicon dioxide material, is formed above the strain-inducing material so as to provide superior patterning conditions upon removing an unwanted portion of the compressively stressed dielectric material from the remaining portion of the initially deposited tensile stressed layer. Consequently, after the removal of a corresponding resist mask or patterning the second strain-inducing dielectric material, a tensile stressed dielectric material is selectively formed above the N-channel transistor, while a compressively stressed dielectric material is selectively formed above the P-channel transistor. Thereafter, any further interlayer dielectric material, for instance in the form of silicon dioxide and the like, is deposited and patterned so as to form contact elements that connect to the transistors.

Generally, the above-described conventional process sequence is a very efficient strain-inducing mechanism whose efficiency strongly depends on the internal stress level of the dielectric materials, the amount of dielectric materials and the distance of these materials from the channel region and the active region of transistors. Since internal stress levels that are achievable by presently available deposition recipes are restricted to several GPa and since the amount of stressed dielectric material may have to be reduced upon further device scaling as the resulting surface topography in densely packed device areas may restrict the layer thickness of these materials, it is an important aspect to position the highly stressed dielectric material close to the active regions and channel regions in order to enhance the mechanical stress transfer. As described above, however, the etch stop material, i.e., the silicon dioxide layer, formed above the metal silicide regions may thus restrict the efficiency of the strain-inducing mechanism, thereby reducing the overall efficiency, in particular in highly scaled semiconductor devices. Thus, it has been proposed to reduce the thickness of the etch stop layer in order to provide superior strain transfer efficiency, for instance in the N-channel transistor when the tensile stressed dielectric material is deposited first. On the other hand, reducing the thickness of the etch stop layer significantly affects the patterning of the dielectric layer above the P-channel transistor since, during the corresponding plasma-based etch process, severe damage of the metal silicide regions may be created, thereby reducing the overall conductivity and thus increasing the external resistance of the P-channel transistor. Consequently, in conventional strategies, the thickness of the etch stop layer is selected so as to obtain a compromise between strain transfer efficiency in one transistor and keeping the degree of resistance increase at an acceptable level in the other type of transistor. Consequently, upon further reducing the overall transistor dimensions, however, an over-proportional reduction of the strain-inducing mechanism may be observed, since at a certain level the thickness of the silicon dioxide layer may not be reduced without causing significant transistor degradation in the other type of transistor.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure contemplates manufacturing techniques in which strain-inducing material layers may be formed above transistors without requiring an under-lying etch stop material, while at the same time integrity of sensitive device areas, such as metal silicide regions, may be preserved. To this end, an etch stop layer may be provided in an early manufacturing stage selectively on one type of transistor and may be used in a later manufacturing stage in order to pattern a strain-inducing material layer. The etch stop layer may be efficiently removed in a later manufacturing stage prior to depositing a further strain-inducing material layer, thereby obtaining a device configuration in which the strain-inducing material layers of different type of stress level may be positioned so as to be in direct contact with the corresponding transistors, thereby providing superior strain conditions in the corresponding active regions. Moreover, the process flow may guarantee integrity of sensitive device areas, such as metal silicide regions, since, in some illustrative embodiments, these regions may be provided sequentially for the complementary transistors so that the corresponding patterning process may be performed prior to actually implementing the metal silicide regions. Moreover, the etch stop material may be provided with a sufficient thickness so as to suppress any undue etch-related damaged of underlying device areas. Consequently, by using a sacrificial etch stop layer for N-channel transistors and P-channel transistors, i.e., the etch stop layer is removed from both types of transistors, generally enhanced transistor performance may be accomplished without jeopardizing the integrity of sensitive device areas, such as metal silicide regions.

One illustrative method disclosed herein comprises forming a hard mask so as to expose a first transistor and mask a second transistor of a semiconductor device. The method further comprises forming a first metal silicide selectively in the first transistor by using the hard mask as a silicidation mask. Moreover, a first strain-inducing dielectric layer is formed above the first and second transistors. The method further comprises removing the first strain-inducing dielectric layer selectively from above the second transistor by using the hard mask as an etch stop layer. Additionally, the hard mask is removed from above the second transistor and a second metal silicide is formed selectively in the second transistor in the presence of the first strain-inducing dielectric layer that is formed above the first transistor. Additionally, the method comprises forming a second strain-inducing dielectric layer selectively above the second transistor.

A further illustrative method disclosed herein comprises forming a first metal silicide in a first transistor while masking a second transistor with a hard mask. Additionally, the method comprises forming a first strain-inducing layer selectively above the first transistor by using a hard mask as an etch stop layer. Moreover, the hard mask is removed from above the second transistor and a second metal silicide is formed in the second transistor in the presence of the first strain-inducing layer that is formed above the first transistor. Additionally, the method comprises forming a second strain-inducing layer above the second transistor.

A still further illustrative method disclosed herein relates to forming a semiconductor device. The method comprises forming a hard mask layer above a gate electrode structure and an active region of a first transistor and above a gate electrode structure and an active region of a second transistor. Moreover, a mask is formed above the hard mask layer and the hard mask layer is removed selectively from above the first transistor by using the mask as an etch mask. Additionally, the method comprises forming deep drain and source regions in the active region of the first transistor by using a mask as an implantation mask. Furthermore, a first strain-inducing layer is formed above the first transistor and the first strain-inducing layer is removed selectively from above the second transistor by using the hard mask layer as an etch stop layer. Furthermore, the method comprises removing the hard mask layer from above the second transistor and forming a second strain-inducing layer above the second transistor.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1q schematically illustrate cross-sectional views of a semiconductor device during various manufacturing stages for forming a semiconductor device so as to implement strain-inducing material layers of different types of strain above corresponding transistors on the basis of a sacrificial etch stop layer, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides manufacturing techniques in which a strain-inducing material layer, such as a highly stressed silicon nitride material and the like, may be formed so as to be in direct contact for any type of transistors, such as N-channel transistors and P-channel transistors, while at the same time an influence of the patterning of the highly stressed dielectric materials on sensitive device areas, such as metal silicide regions, may be avoided or at least significantly reduced. To this end, an efficient etch stop material, such as a silicon dioxide layer and the like, may be provided in an early manufacturing stage with an appropriate thickness that is not restricted by any strain efficiency considerations, as may be the case in conventional strategies, as described above. The sacrificial etch stop layer is then patterned so as to be provided above one type of transistor in which a strain-inducing material layer is to be removed in a later manufacturing stage. In some illustrative embodiments, the patterning of the sacrificial etch stop layer may be accomplished prior to forming metal silicide regions, thereby avoiding undue damage of any such sensitive device regions. To this end, the metal silicide material may be provided after the patterning of the sacrificial etch stop layer for one type of transistor while efficiently using the remaining portion of the etch stop layer as a silicidation mask. On the other hand, in a later manufacturing stage, the remaining portion of the etch stop layer may be efficiently removed, after the patterning of the first strain-inducing material layer, so that subsequently metal silicide regions may be formed in the other type of transistor without being affected by the patterning of any strain-inducing material layers. Thus, after the removal of the etch stop layer, a further strain-inducing material layer may be deposited so as to be in direct contact with the corresponding transistor, thereby achieving superior strain transfer efficiency and providing metal silicide regions of superior integrity.

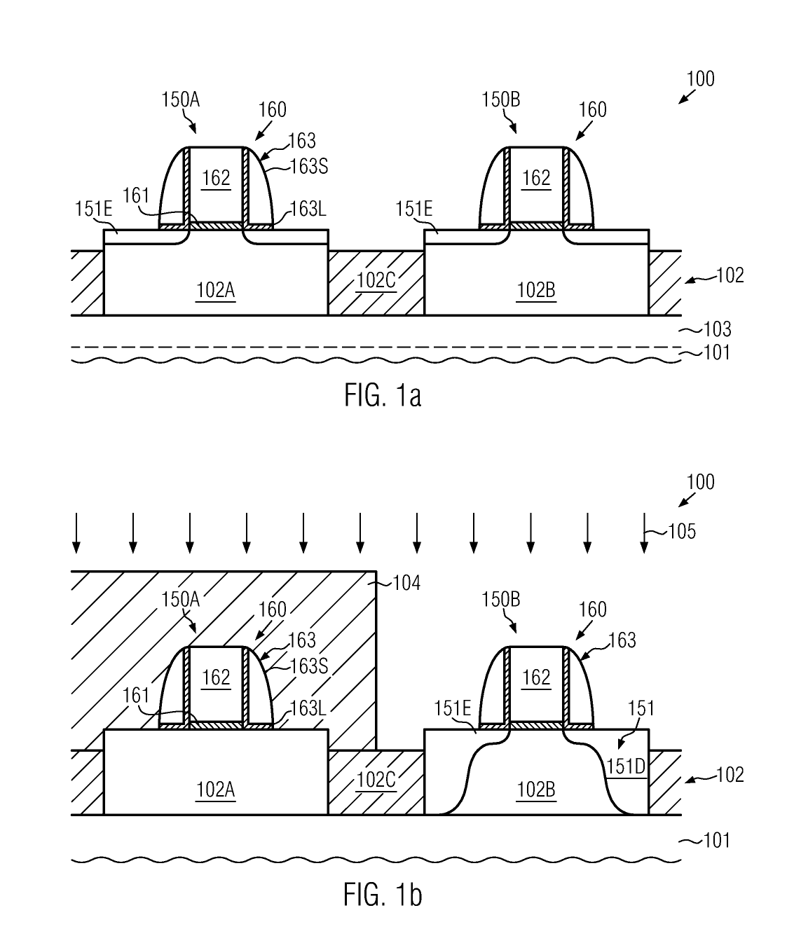

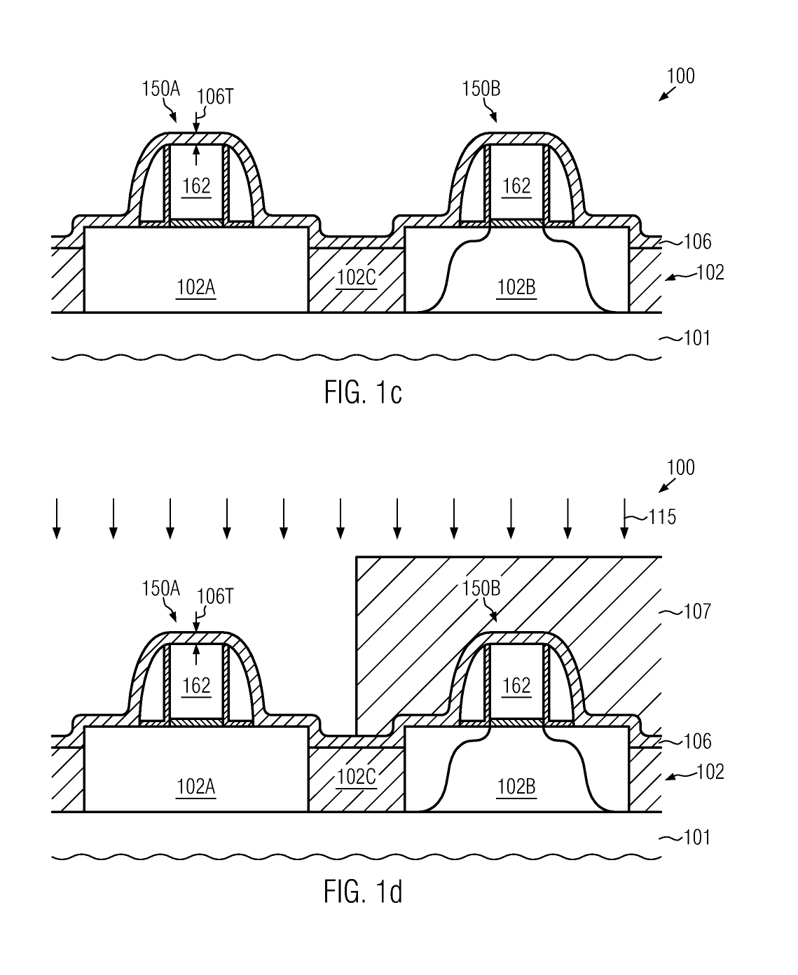

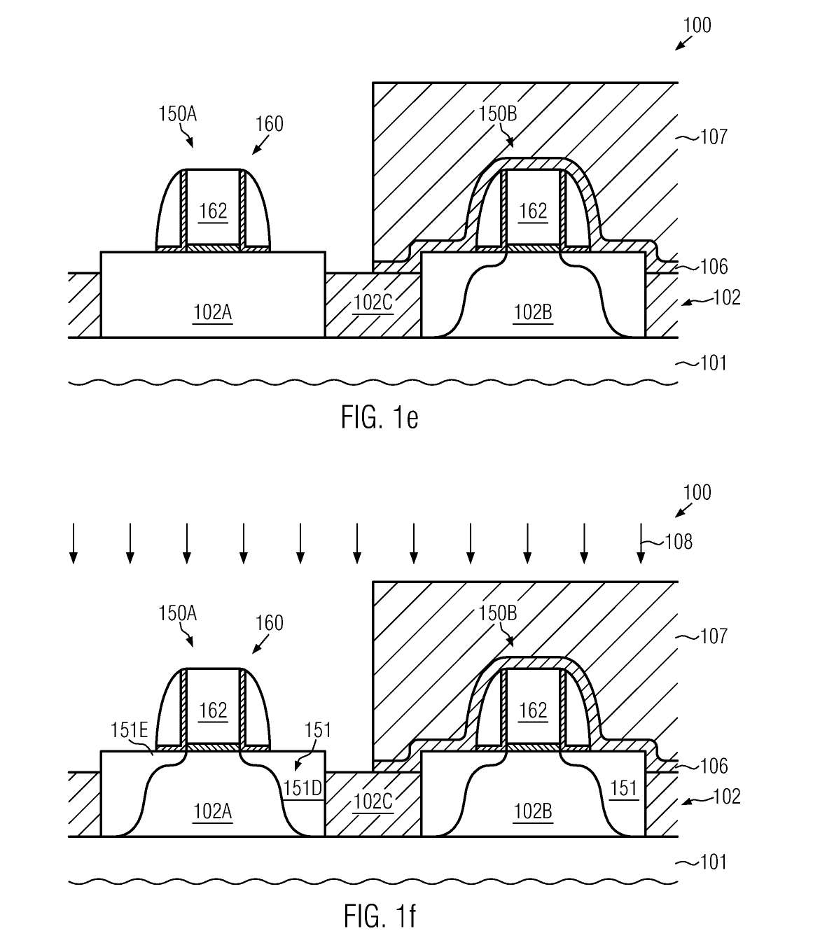

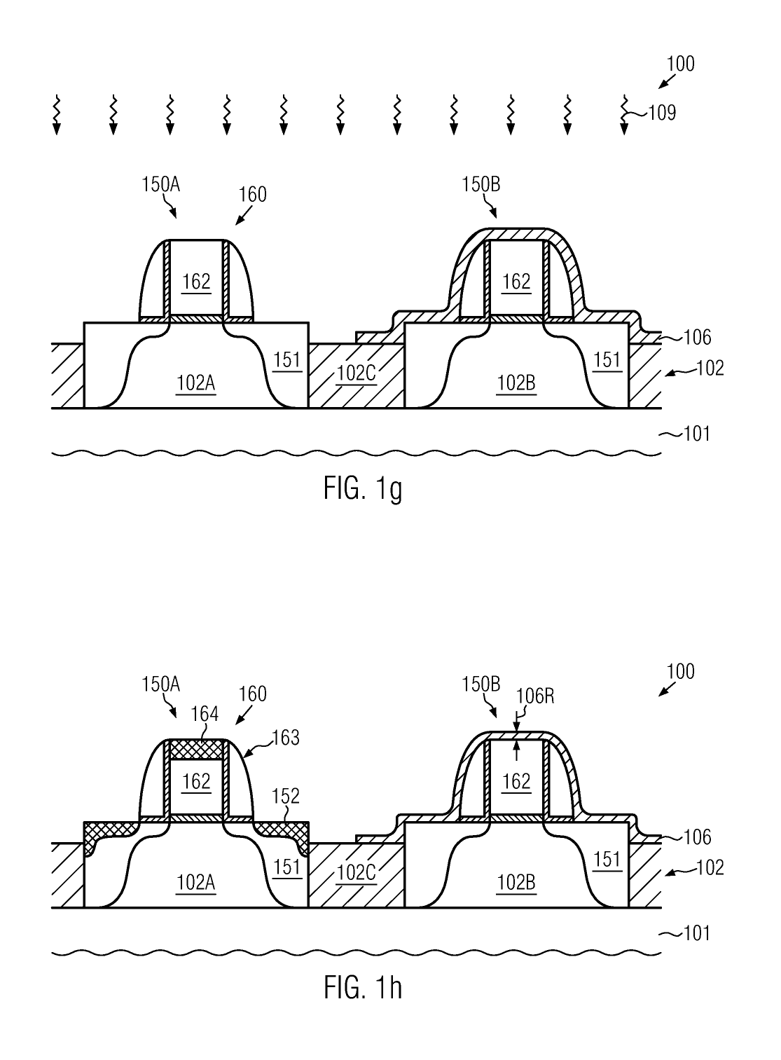

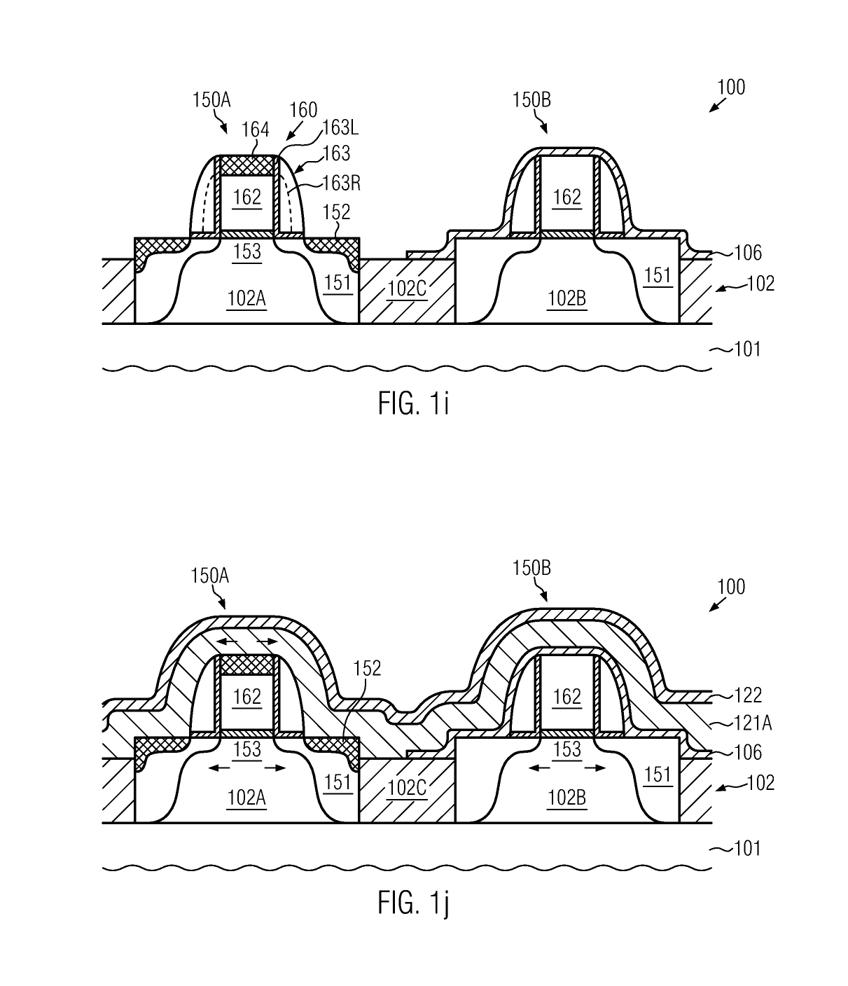

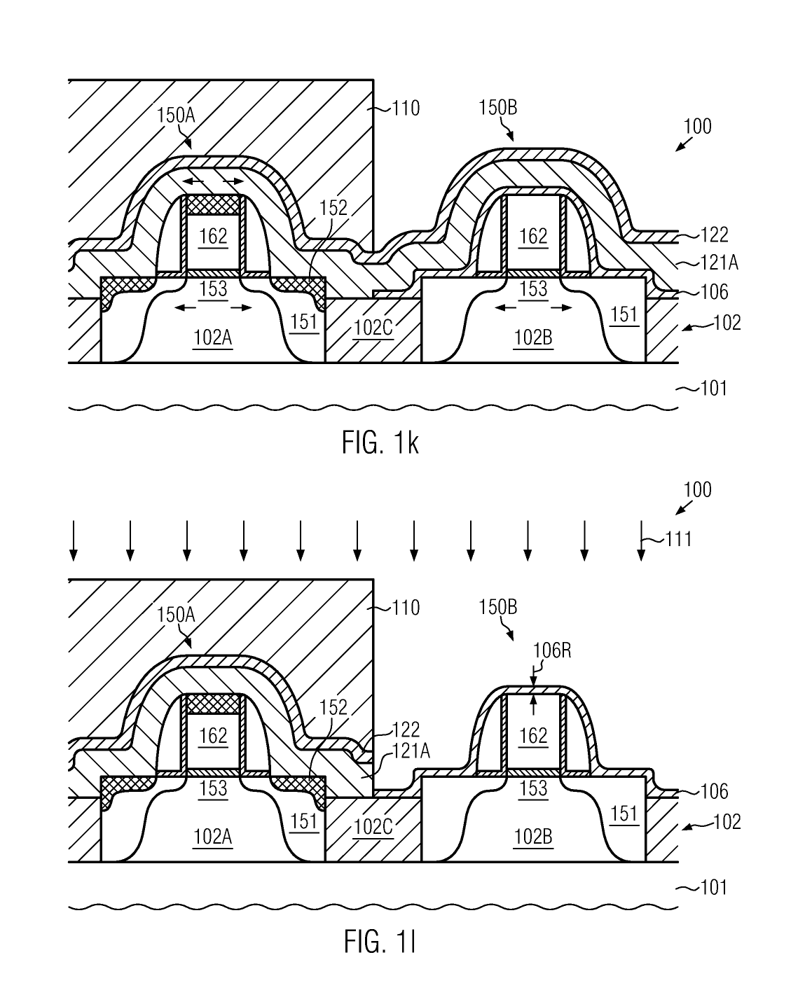

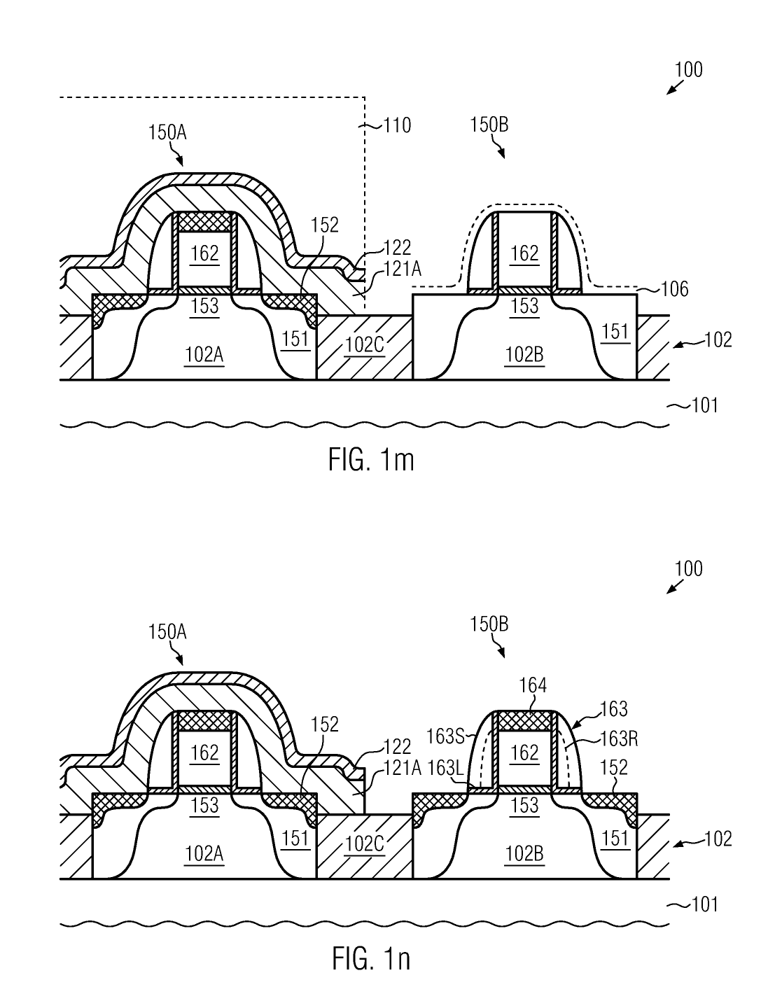

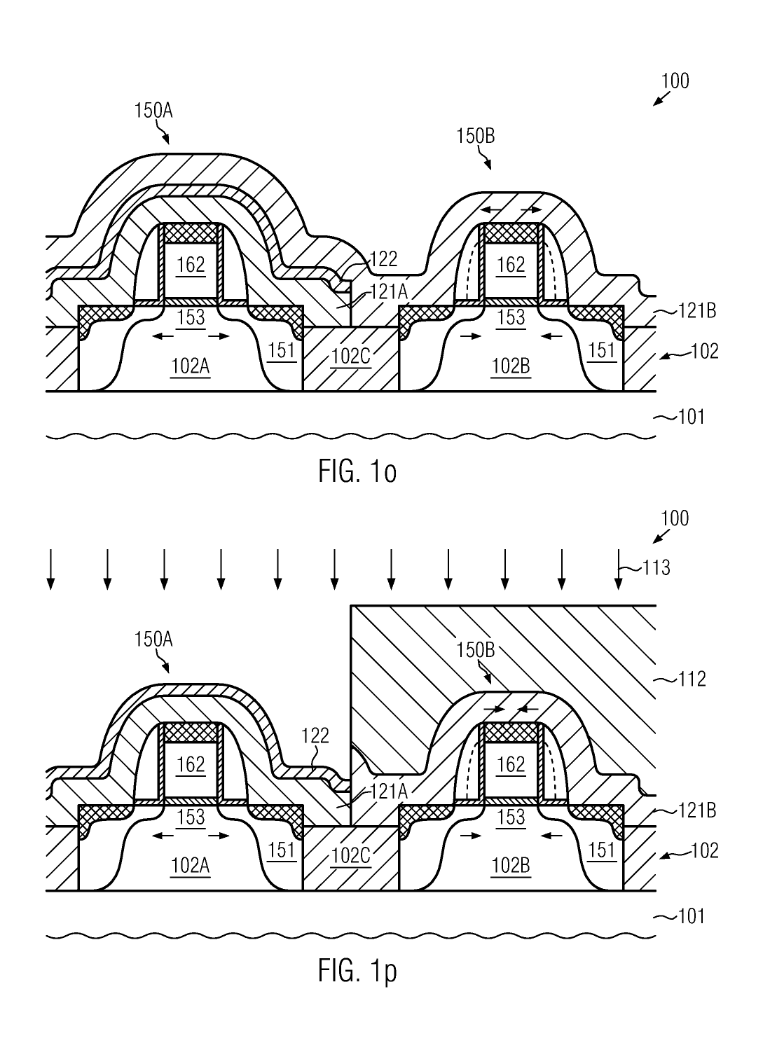

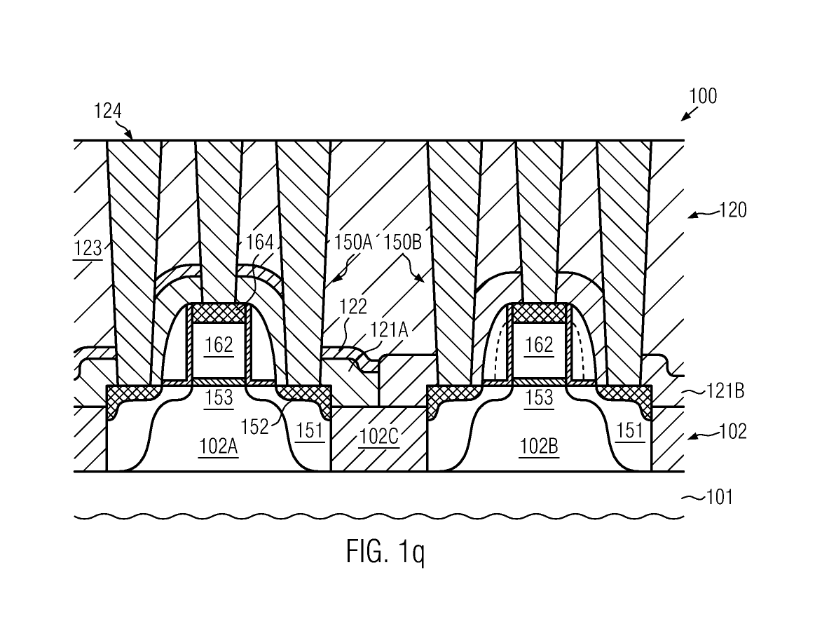

FIG. 1a schematically illustrates a cross-sectional view of a semiconductor device 100, which may comprise a substrate 101 and a semiconductor layer 102, in which a plurality of active regions or semiconductor regions 102A, 102B may be provided. Generally, an active region is to be understood as a semiconductor region in and above which one or more transistors are to be formed. In the embodiment shown, the active region 102A may correspond to a first transistor 150A, such as an N-channel transistor or a P-channel transistor, while the second active region 102B may correspond to a second transistor 150B, such as a P-channel transistor or an N-channel transistor. In some illustrative embodiments, the transistors 150A, 150B may represent complementary transistors, i.e., transistors of inverse conductivity type. In some illustrative embodiments, the active regions 102A, 102B may be provided in the form of a silicon-on-insulator (SOI) architecture when a buried insulating material 103 is positioned below the semiconductor layer 102. Moreover, in the manufacturing stage shown, the transistors 150A, 150B may comprise gate electrode structures 160, which in turn may include a gate dielectric material 161 and an electrode material 162. Furthermore, the gate electrode structures 160 may comprise a sidewall spacer structure 163, which may include a plurality of liner materials and offset spacers which, for convenience, are not shown in FIG. 1a. Moreover, the spacer structure 163 may comprise at least an outer spacer element 163S in combination with an etch top liner 163L, which in combination may serve so as to adjust a lateral offset of deep drain and source regions of metal silicide regions still to be formed. It should be appreciated that the gate electrode structures 160 may have any appropriate configuration in terms of gate length, material composition and the like. For example, a length of the gate electrode structures 160, i.e., the horizontal extension of the electrode material 162 at the gate dielectric material 161 in FIG. 1a may be 100 nm and significantly less, such as 50 nm and less in highly sophisticated semiconductor devices. Furthermore, the gate dielectric material 161 may comprise conventional dielectric materials, such as silicon dioxide, silicon oxynitride and the like, while in other cases, in addition to or alternatively to these conventional dielectric materials, also high-k dielectric material, i.e., dielectric materials having a dielectric constant of 10.0 and higher, may be provided. Similarly, the electrode material 162 may comprise a semiconductor base material, possibly in combination with metal-containing electrode materials, such as titanium nitride and the like, in particular when a high-k dielectric material may be included in the gate dielectric layers 161.

Furthermore, in the manufacturing stage shown, drain and source extension regions 151E may be provided in the active regions 102A, 102B, possibly in combination with other implant areas (not shown), such as counter-doping regions and the like.

The semiconductor device 100 as illustrated in FIG. 1a may be formed on the basis of any appropriate process strategy. That is, the isolation regions 102C may be formed so as to laterally delineate the active regions 102A, 102B, which may be accomplished on the basis of appropriate lithography, etch, deposition and planarization techniques prior to or after the basic doping of the active regions 102A, 102B may be implemented, for instance by performing respective implantation and masking steps. Next, appropriate material layers for gate electrode structures 160 may be formed, for instance by oxidation and/or deposition, while also additional material, such as hard mask materials and the like, may be provided, depending on the lithography and patterning strategy to be used for patterning the materials 162 and 161. Thereafter, any additional liners or spacers may be formed, for instance, by deposition and etch techniques, followed by the incorporation of the drain and source dopant species for forming the extension regions 151E. If required, any additional anneal processes may be performed in order to activate the dopants and re-crystallize implantation-induced damage. Next, the spacer structure 163 may be formed or completed by depositing appropriate materials and patterning the same. For example, the etch stop liner 163L may be provided in the form of a silicon dioxide material, while the spacer element 163S may be provided in the form of a silicon nitride material. It should be appreciated, however, that any other material composition may be applied.

FIG. 1b schematically illustrates the device 100 with a resist mask or any other appropriate mask material 104 formed so as to cover the transistor 150A, while exposing the transistor 150B to an implantation process 105 in order to incorporate a further drain and source dopant species for deep drain and source regions 151D of the transistor 150B. Consequently, the deep drain and source regions 151D in combination with the previously formed extension regions 151E may form drain and source regions 151, wherein a final dopant profile may be adjusted in a later manufacturing stage, for instance by performing an appropriate anneal process. Thereafter, the mask 104 may be removed by well-established resist removal processes and the like.

FIG. 1c schematically illustrates the semiconductor device 100 in a further advanced manufacturing stage in which a hard mask layer 106, such as a silicon dioxide material and the like, may be formed above the transistors 150A, 150B. In other cases, the layer 106 may be comprised of any other material, which may provide superior etch stop capabilities during the further processing and which may also be usable as a silicidation mask in some illustrative embodiments during the further processing. The hard mask layer 106 may be provided with an appropriate initial thickness 106T, which may be selected so as to provide the required integrity of any underlying device areas and to comply with the requirements of the further processing of the device 100. It should be appreciated that the hard mask layer 106 is a sacrificial material layer for both the transistor 150A and the transistor 150B so that any negative effect on the strain transfer efficiency of any highly stressed material layers still to be provided may be avoided.

FIG. 1d schematically illustrates the semiconductor device 100 with a further mask 107 formed above the hard mask layer 106. The mask 107 may be provided in the form of a resist material and the like. To this end, any well-established lithography techniques may be applied. Moreover, the device 100 may be exposed to an etch process 115, which may be designed so as to remove the exposed portion of the hard mask layer 106 selectively with respect to other device areas. For example, in some illustrative embodiments, a wet chemical etch chemistry may be applied, for instance on the basis of hydrofluoric acid (HF) when the layer 106 is comprised of silicon dioxide. In this manner, the material 106 may be patterned without undue damage to any underlying device areas, such as the active region 102A.

FIG. 1e schematically illustrates the semiconductor device 100 after the removal of the exposed portion of the hard mask layer 106. Consequently, the gate electrode structure 160 and the active region 102A of the transistor 150A may be exposed and may be prepared for the further processing of the device 100. In some illustrative embodiments, the etch mask 107 may still be in place and may be used during the further processing. In other cases, if considered appropriate, the mask 107 may be removed.

FIG. 1f schematically illustrates the device 100 when exposed to an ion implantation process 108, in which drain and source dopant species may be incorporated into the active region 102A in order to form deep drain and source regions 151D therein, which, in combination with the previously formed extension region 151E, may form the drain and source regions 151 of the transistor 150A. In the embodiment shown, the mask 107 may still be present and may be used as an implantation mask, thereby providing a very efficient manufacturing sequence since no additional lithography steps may be required for patterning the hard mask layer 106. Thereafter, the mask 107 may be removed and any further processes, such as cleaning processes, if required, may be performed.

FIG. 1g schematically illustrates the device 100 in a manufacturing stage in which one or more anneal processes 109 may be applied in order to activate the dopant species of the drain and source regions 151, thereby also re-crystallizing implantation-induced damage. Furthermore, during the process 109, a certain degree of dopant diffusion may be initiated, if considered appropriate, in order to adjust the final profile of the drain and source regions 151. Thereafter, the device 100 may be prepared for forming metal silicide regions selectively in the transistor 150A. To this end, well-established cleaning recipes may be applied, wherein the hard mask 106 may preserve integrity of the transistor 150B. It should be appreciated that a certain degree of material erosion of the hard mask 106 may be readily taken into consideration upon selecting the initial layer thickness of the layer 106.

FIG. 1h schematically illustrates the device 100 with metal silicide regions 152 selectively formed in the drain and source regions 151 of the transistor 150A. Moreover, depending on the configuration of the gate electrode structure 160, also a metal silicide region 164 may be formed therein. On the other hand, the transistor 150B may still be covered by the hard mask 106, which may have a reduced thickness 106R, which may have been caused by a certain material loss during the previous processing for cleaning and preparing the transistor 150A for the formation of the metal silicide regions 152, 164. The silicidation process may be performed on the basis of any appropriate process strategy, i.e., by depositing one or more refractory metals and heat treating the resulting layer stack so as to initiate the chemical reaction between silicon and the refractory metal, wherein any dielectric surface areas, such as the spacer structure 163 in the transistor 150A and the hard mask 106 may avoid the formation of a metal silicide.

FIG. 1i schematically illustrates the semiconductor device 100 according to further illustrative embodiments in which, prior to forming the metal silicide regions 152, 164, the spacer element 163 may be reduced in size or may be completely removed, as indicated by the dashed spacer element 163R, which may be accomplished on the basis of selective etch techniques, wherein the liner 163L may act as an efficient etch stop material. Consequently, in this case, the liner 163L may substantially determine the lateral offset of the metal silicide regions 152. On the other hand, using a reduced spacer 163R or even a completely removed spacer for the further processing of the device 100 may result in superior strain transfer efficiency, since any highly stressed material layers may be positioned closer to the active region and a channel region 153. It should be appreciated that the high degree of flexibility in adjusting the transistor characteristics may be achieved since the silicidation process, the type of metal silicide and also the degree of spacer reduction may be adjusted individually for the transistor 150A, while the transistor 150B is still reliably covered by the hard mask 106.

FIG. 1j schematically illustrates the device 100 in a further advanced manufacturing stage. As shown, a strain-inducing material layer 121A, such as a silicon nitride material and the like, may be formed above the transistors 150A and 150B, wherein the material 121A may be in direct contact with the transistor 150A, while the material 121A is formed on or above the hard mask layer 106 in the transistor 150B. In this context, a “direct” contact between the material 121A and the transistor 150A is to be understood such that the material 121A may be formed directly on the metal silicide regions 152. As discussed above, the material 121A may be provided with a high internal stress level, for instance a tensile stress level, thereby also creating a tensile strain in the channel regions 153 of the first and second transistors 150A, 150B, wherein, however, the tensile strain level of the transistor 150B may be significantly less due to the presence of the hard mask 106. Moreover, an etch stop or etch control layer 122 may be formed on the material 121A, for instance in the form of a silicon dioxide material and the like, in order to enhance the process conditions upon patterning a further highly stressed material layer that is still to be formed. As discussed above, the layer 121A may be deposited on the basis of well-established plasma enhanced chemical vapor deposition (CVD) techniques, for instance in the form of a silicon nitride material, while the etch control layer 122 may be formed by deposition techniques in the form of a silicon dioxide material. In other cases, the layer 122 may be formed on the basis of a plasma treatment so as to “oxidize” a surface portion of the layer 121A, thereby enabling a very “conformal” formation of the layer 122, which may be advantageous in highly scaled semiconductor devices in which pronounced surface topography may exist between closely spaced gate electrode structures.

FIG. 1k schematically illustrates the semiconductor device 100 in a manufacturing stage in which an etch mask 110, such as a resist mask, covers the transistor 150A, i.e., the material layers 122 and 121A formed thereabove, while these layers are exposed above the transistor 150B. Next, the layer 122 may be removed on the basis of an appropriate etch chemistry, followed by a further etch process for etching into the layer 121A.

FIG. 11 schematically illustrates the device 100 during a corresponding etch process or etch sequence 111, which may be performed on the basis of the mask 110 in order to remove the layers 122 and 121A selectively from above the transistor 150B. At least during an etch step for removing the exposed portion of the layer 121A, a selective etch recipe may be applied in which the hard mask 106 may act as an efficient etch stop material, thereby avoiding or at least significantly reducing any effect on underlying device areas, such as the drain and source regions 151. As also discussed above, during the corresponding phase of the etch process 111, the remaining thickness 106R of the hard mask 106 is appropriately selected so as to provide superior integrity of any underlying device area, which may be accomplished by appropriately selecting the initial layer thickness, as explained before.

FIG. 1m schematically illustrates the semiconductor device 100 in a further advanced manufacturing stage, i.e., after the removal of the hard mask 106 and the etch mask 110. To this end, the hard mask 106 may be removed, for instance, by selective wet chemical etch recipes, for instance in the form of HF, in the presence of the mask 110, thereby avoiding undue damage of the exposed portions of the drain and source regions 151 in the transistor 150B, while also integrity of the layer 122 may be substantially preserved. Thereafter, cleaning processes may be applied, if considered necessary, and thereafter the transistor 150B may be prepared for the formation of a metal silicide, while the transistor 150A may be reliably covered by the layer 122.

FIG. 1n schematically illustrates the semiconductor device 100 in a further advanced manufacturing stage. As illustrated, metal silicide regions 152 may be formed in the drain and source regions 151 of the transistor 150B and possibly a metal silicide region 164 may be formed in the gate electrode structure 160. To this end, any appropriate silicidation technique may be applied, wherein the layers 122 and 121A may preserve integrity of the transistor 150A. Moreover, as illustrated, also in this case, if desired, a reduction of spacer width, as indicated by 163R, or a complete removal of the spacer 163S, may be initiated if considered appropriate. In this case, the lateral offset of the metal silicide regions 152 may be determined by the etch stop liner 163L. As discussed before, due to the sequential formation of the metal silicide regions 152, 164 for the transistors 150A, 150B, an individual adaptation may be accomplished if considered appropriate, for instance in terms of material composition and a reduction in spacer width, thereby obtaining an additional parameter for individually adjusting the finally obtained transistor characteristics.

FIG. 1o schematically illustrates the device 100 in a stage in which a further strain-inducing material layer 121B is formed above the transistors 150A, 150B. For example, the material layer 121B may be provided in the form of a silicon nitride material, a nitrogen-containing silicon carbide material and the like, wherein, in the embodiment shown, a high compressive stress level may be induced upon depositing the material 121B. Consequently, the layer 121B may be formed “on” the transistor 150B, that is, the layer 121B may be in direct contact with the drain and source regions 151, i.e., with the metal silicide regions 152 formed therein. Consequently, a corresponding compressive strain may be induced in the channel region 153. The deposition of the material layer 121B may be accomplished on the basis of any appropriate deposition technique, as is also described above.

FIG. 1p schematically illustrates the device 100 in a further advanced manufacturing stage in which an etch mask 112 is formed above the transistor 150B in order to expose the material layer 121B to an etch ambient 113, which may be established on the basis of any appropriate technique, such as plasma assisted etch recipes, wherein the process 113 may be controlled or stopped on the basis of the layer 122. Consequently, the layers 121A, 121B are provided above the corresponding transistors 150A, 150B so as to induce the desired type of strain in the channel regions 153, wherein the overall strain transfer efficiency is enhanced due to the absence of any underlying etch stop layer, as may typically be present, at least for one type of transistor, according to the conventional process flow, as discussed above.

FIG. 1q schematically illustrates the semiconductor device 100 in a further advanced manufacturing stage. As illustrated, a contact level 120 may be provided and may comprise the strain-inducing material layers 121A, 121B and at least a further interlayer dielectric material 123, such as a silicon oxide material. In some cases, the material layer 122 may still be present, while in other cases this material may be removed prior to the deposition of the material 123, if considered appropriate. Moreover, the contact level 120 may comprise contact elements 124, which may connect to the transistors 150A, 150B according to any appropriate contact regime. The contact level 120 may be formed on the basis of any appropriate process strategy, i.e., depositing the material 123, planarizing the material 123 and patterning the same on the basis of sophisticated lithography techniques in order to form contact openings, which are subsequently filled with an appropriate conductive material. Thereafter, any excess material may be removed, for instance by chemical mechanical polishing (CMP), thereby providing the contact elements as electrically isolated elements.

As a result, the present disclosure provides manufacturing techniques in which an efficient strain-inducing mechanism may be implemented, for instance in SOI devices, by providing highly stressed material layers above different types of transistors without providing an intermediate etch stop material. That is, the highly stressed material layers may be in direct contact with the corresponding transistor, thereby enhancing the overall strain transfer efficiency. Moreover, undue influence on sensitive device regions, such as metal silicide regions, may be avoided by providing the corresponding metal silicide regions in a sequential manner for the transistors, thereby enabling the formation of metal silicide regions in one type of transistor after the patterning of the first strain-inducing material layer. Moreover, the process flow including the sequential formation of the metal silicide regions may provide superior flexibility in adjusting the overall transistor characteristics. It should be appreciated that, in the above-illustrated embodiments, the first transistor 150A is a transistor that requires a tensile strained component while the second transistor 150B may require a compressive strain, where the tensile stressed dielectric material is provided first. In other illustrative embodiments, the reverse sequence of process steps may be applied in which the compressive stress material layer may be formed first and may be patterned on the basis of the sacrificial hard mask. For example, referring to FIG. 1g, the transistor 150B may then represent a transistor requiring a tensile strained component that after forming metal silicide regions in the transistor 150A, a corresponding compressive strain-inducing material layer may be formed first and may be removed from above the transistor 150B on the basis of the hard mask 106. Moreover, in this case, during the anneal process 109, an additional tensile strained component may be induced in the active region 102B, since the drain and source regions 151 may be in a highly damaged state upon forming the hard mask 106, which may then be re-crystallized during the anneal process 109 in the presence of the hard mask 106, thereby inducing a regrowth of the previously amorphized drain and source regions 151 in a strained state. Moreover, irrespective of the sequence of applying the tensile stressed and the compressive stressed material layer, inferior integrity of the metal silicide regions may be accomplished by avoiding exposure to any reactive process atmosphere used for patterning the strain-inducing material layers.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a hard mask so as to expose a first transistor and mask a second transistor of a semiconductor device;
forming a first metal silicide selectively in said first transistor by using said hard mask as a silicidation mask;
forming a first strain-inducing dielectric layer above said first and second transistors;
removing said first strain-inducing dielectric layer selectively from above said second transistor by using said hard mask as an etch stop layer;
removing said hard mask from above said second transistor;
forming a second metal silicide selectively in said second transistor in the presence of said first strain-inducing dielectric layer formed above said first transistor; and
forming a second strain-inducing dielectric layer selectively above said second transistor.

2. The method of claim 1, further comprising forming deep drain and source regions of said second transistor prior to forming said hard mask.

3. The method of claim 2, further comprising forming deep drain and source regions of said first transistor after forming said hard mask.

4. The method of claim 3, wherein forming said hard mask comprises forming a resist mask above said second transistor and removing an exposed portion of mask layer so as to form said hard mask, wherein said method further comprises using said resist mask for forming said deep drain and source regions of said first transistor.

5. The method of claim 1, further comprising an etch control layer above said first strain-inducing dielectric layer.

6. The method of claim 1, further comprising removing said second strain-inducing dielectric layer selectively from above said first transistor.

7. The method of claim 1, further comprising reducing a width of a sidewall spacer structure of a gate electrode structure of said first transistor prior to forming said first metal silicide.

8. The method of claim 1, further comprising reducing a width of a sidewall spacer structure of a gate electrode structure of said second transistor prior to forming said second metal silicide and after forming said first metal silicide.

9. The method of claim 1, wherein said first and second transistors are complementary transistors.

10. A method, comprising:
forming a first metal silicide in a first transistor while masking a second transistor with a hard mask;
forming a first strain-inducing layer selectively above said first transistor by using said hard mask as an etch stop layer;
removing said hard mask from above said second transistor;
forming a second metal silicide in said second transistor in the presence of said first strain-inducing layer formed above said first transistor; and
forming a second strain-inducing layer above said second transistor.

11. The method of claim 10, wherein said first and second strain-inducing layers induce a different type of strain.

12. The method of claim 10, further comprising forming said hard mask after forming deep drain and source regions of said first transistor prior to forming deep drain and source regions of said second transistor.

13. The method of claim 12, wherein forming said hard mask comprises forming a mask layer above said first and second transistors, forming a mask, removing said mask layer from above said first transistor and forming said deep drain and source regions by using said mask as an implantation mask.

14. The method of claim 10, further comprising forming an etch control layer on said first strain-inducing layer and using said etch control layer so as to remove said second strain-inducing layer selectively from above said first transistor.

15. The method of claim 10, further comprising reducing a width of a sidewall spacer structure of a gate electrode structure of said first transistor prior to forming said first metal silicide.

16. The method of claim 10, further comprising reducing a width of a sidewall spacer structure of a gate electrode structure of said second transistor prior to forming said second metal silicide and after forming said first metal silicide.

17. A method of forming a semiconductor device, the method comprising:
forming a hard mask layer above a gate electrode structure and an active region of a first transistor and above a gate electrode structure and an active region of a second transistor;
forming a mask above said hard mask layer;
removing said hard mask layer selectively from above said first transistor by using said mask as an etch mask;
forming deep drain and source regions in said active region of said first transistor by using said mask as an implantation mask;
forming a first strain-inducing layer above said first transistor;
removing said first strain-inducing layer selectively from above said second transistor by using said hard mask layer as an etch stop layer;
removing said hard mask layer from above said second transistor; and
forming a second strain-inducing layer above said second transistor.

18. The method of claim 17, further comprising forming a first metal silicide in said active region of said first transistor by using said hard mask layer formed above said second transistor as a silicidation mask.

19. The method of claim 17, further comprising forming a second metal silicide in said active region of said second transistor after removing said hard mask layer from above said second transistor.

20. The method of claim 17, wherein said first and second transistor are complementary transistors and said first and second strain-inducing layer induce different types of strain.
